(19) United States
(12) Patent Application Publication
(10) Pub. No.: US 2016/0211395 A1
(43) Pub. Date: Jul. 21, 2016

(54) METHOD FOR LASER-STRUCTURING THIN LAYERS ON A SUBSTRATE IN ORDER TO PRODUCE MONOLITHICALLY CONNECTED THIN-LAYER SOLAR CELLS, AND METHOD FOR PRODUCING A THIN-LAYER SOLAR MODULE

(71) Applicant: BEIJING APOLLO DING RONG SOLAR TECHNOLOGY CO., LTD., Beijing (CN)

(72) Inventors: Dirk HERRMANN, Stadecken-Elsheim (DE); Stephan MARSCHALL, Leipzig (DE); Patrick MENDE, Leipzig (DE)

(73) Assignee: BEIJING APOLLO DING RONG SOLAR TECHNOLOGY CO., LTD., Beijing (CN)

(21) Appl. No.: 14/914,770

(22) PCT Filed: Aug. 28, 2014
(86) PCT No.: PCT/DE2014/100309

§ 371 Date: Feb. 26, 2016

(30) Foreign Application Priority Data
Aug. 30, 2013 (DE) 10 2013 109 480.5

(51) Int. Cl. H01L 31/0463; H01L 31/0224; H01L 31/048; H01L 31/18

(52) U.S. Cl. CPC H01L 31/0463; H01L 31/186; H01L 31/022441; H01L 31/048

(57) ABSTRACT

The invention relates to a method for laser-structuring thin layers on a substrate in order to produce monolithically connected thin-layer solar cells, having the following steps:—providing a laser with a laser wavelength,—providing a substrate (1) which comprises a first side and a second side and which is transparent for the laser wavelength, said first side of the substrate has big a metal rear electrode thin layer (2), on which an absorber thin layer (3) for thin layer solar cells is arranged,—emitting a laser beam (L) onto the substrate, and—moving the laser beam (L) over the substrate (1) along a writing line and/or moving the substrate (1) relative to the laser beam (L) along a writing line. According to the invention, the laser beam (L) is emitted onto the second side of the substrate (1) and is incident on the metal rear electrode thin layer (2) through the substrate (1), and laser pulses of the laser beam are adjusted in the nano-, pico-, or femtosecond range and the laser beam is moved such that the absorber thin layer (3) arranged over the metal rear electrode thin layer (2) is detached along the writing line, Hid a laser-influenced metal rear electrode thin layer (2) remains on the substrate.

The invention relates to a method for the laser structuring of thin films on a substrate for the production of monolithically interconnected thin-film solar cells and also to a method for producing a thin-film solar module.

Thin-film solar modules usually comprise thin-film solar cells that are monolithically interconnected to one another in series. For producing the monolithic interconnection of the thin-film solar cells in a substrate structure, first a back-electrode thin film is deposited on the substrate. The substrate may be formed as a glass plate with a thickness of for example three millimeters and the back-electrode thin film may be formed from metal, for example from molybdenum, with a film thickness of several hundred nanometers. This back-electrode thin film is divided into a plurality of adjacent strips in a first structuring step, which is often also referred to as P1 structuring. Running between these strips of the back-electrode thin film are narrow trenches with a width of usually less than one millimeter, where the back-electrode thin film has been removed by the P1 structuring step in order to insulate the individual strips electrically from one another. The P1 structuring step is usually performed. with the aid of a laser, the beam of which impinges on the back-electrode thin film and vaporizes, sublimates and/or ablates it along scribing lines, and thereby forms the so-called P1 trenches.

An absorber thin film subsequently deposited on these structured strips of the back-electrode thin film, extending over the full surface area of the structured strips and the P1 trenches lying in between. This absorber thin film may consist of a number of sub-films and usually has a thickness of less than two micrometers. There then follows a process referred to as the P2 structuring step. This involves the absorber thin film being removed down to the back-electrode thin film along the so-called P2 trenches adjacent the covered P1 trenches.

After that, a transparent front-side electrode thin film is deposited over the full surface area of the absorber thin film structured with the P2 trenches.

This is followed by the so-called P3 structuring. Once again adjacent and parallel to the covered P2 trenches, the film assembly comprising the absorber thin film and the front-side electrode thin film is removed along so-called P3 trenches down to the back-electrode thin film. The P3 trench lies as close as possible to the P2 trench, but the minimum P2 and P3 trench spacing is limited by the finite measuring and positioning accuracy.

After completion of the sequence of thin-film depositions and P1, P2 and P3 structuring, a multiplicity of thin-film solar cells monolithically interconnected to one another in series is obtained, forming a thin-film solar module. The closer the P2 and P3 trenches can be positioned in relation to one another, the more the absorber thin film can be utilized as an active zone of the interconnected thin-film solar cells.

In particular in the case of a back-electrode thin film of metal, for example of molybdenum, the P2 and P3 structuring steps are carried out mechanically with the aid of thin needles. Effects of wear occur on these needles and the mechanical accuracy in the positioning of the needles is limited in the range of several tenths of a millimeter or, for higher accuracies, requires a disproportionately great expenditure. Also, when needles are used for the structuring, it often happens that the back-electrode thin film is adversely affected in such a way that the efficiency of the solar module is reduced.

WO 2012/051574 A2 discloses a method for producing thin-film solar modules in which the P2 and P3 structuring in particular is carried out by means of a laser. This method comprises the following steps:
providing a laser of a laser wavelength,
providing a substrate having a first side and a second side, which is transparent for the laser wavelength, the first side of the substrate having a metallic back-electrode thin film, and an absorber thin film for thin-film solar cells being arranged on the metallic back-electrode than film,
emitting a laser beam onto the first side of the substrate and
moving the laser beam along a scribing line over the substrate and/or moving the substrate in relation to the laser beam along a scribing line. This method does not preclude the possibility of thin-film particles that are ablated by the laser radiation returning to the trenches in the structure. These particles may cause a short circuit there between the front-electrode thin film and the back-electrode thin film, in particular after the P3 structuring.

This method is also problematic whenever for example an additional film in the form of an electron collecting network with a film thickness of several micrometers has been applied on the front-electrode thin film. The front-electrode thin film and the electron collecting network together form the front-electrode structure. These conductive structures usually have film thicknesses in the range up to 10 μm. This film thickness is much greater in comparison with the thin-film assembly lying thereunder. The laser beam impinging on this structure from the outside is absorbed in the film and no longer has an effect right into the thin-film assembly lying thereunder. Consequently, the required P3 structuring also cannot be produced throughout.

The present invention is based on the object of providing an improved method for the laser structuring of thin films on a substrate for the production of monolithically interconnected thin-film solar cells that overcomes the disadvantages mentioned.

According to the invention, it is provided that the laser beam is emitted onto the second side of the substrate, is incident on the metallic back-electrode thin film through the substrate and is set with laser pulses in the nano-, pico- or femtosecond range and moved in such a way that the absorber thin film arranged over the metallic back-electrode thin film is ablated along the scribing line and a laser-influenced metallic back-electrode thin film remains on the substrate. The claimed time range is understood as meaning the range greater than one femtosecond to less than 1000 nanoseconds.

The invention is based on the surprising finding that, with a rear-side entry of the laser radiation through the substrate that is sufficiently transparent for the laser radiation, parameter windows with which the metallic back-electrode thin film remains largely intact but all of the thin films located on the back-electrode thin film are removed by the interaction with the laser radiation, even film thicknesses of several micrometers, exist for the setting of the laser radiation in combination with the relative movement between the substrate and the laser. This is surprising against the background that the laser radiation that is used has a wavelength for which the metallic back-electrode thin film is not transparent. The decisive parameter is the temporal and spatial variation of the laser energy deposited per unit of volume and unit of time. This depends on parameters such as the wavelength, the pulse duration, the pulse energy, the pulse frequency, the pulse diameter, the beam profile and the relative movement between the laser beam and the substrate. The remaining back-electrode thin film influenced by the laser radiation has usually sacrificed less than 10%, preferably less than 5%, of its film thickness in the region of the structuring trenches. The quality of the film influenced by the laser is better, at least with regard to the efficiency of the solar module, than the quality of the back-electrode thin films remaining after mechanical P2 or P3 structuring.

This finding for carrying out the method makes it possible to carry out both the P2 structuring and the P3 structuring by means of a suitably set laser beam and adapted relative movement between the beam and the substrate. Process parameter windows with which the material is ablated from the thin-film assembly in such a way that no or very few fragments remain in the trench created exist. This also applies to the case where there is not a thin-film assembly as such but a film several micrometers thick deposited in certain portions over the thin-film assembly.

With preference, a variant of the method is therefore devised such that a front-electrode structure is arranged over the absorber thin film and in the region of the scribing line the absorber thin film is ablated together with the front-electrode structure located thereover. This front-electrode structure has one or more thin films of transparent conductive oxide (TCO), for example of doped or undoped zinc oxide, and is for example one micrometer thick.

It is also of advantage to carry out both the P2 structuring and the P3 structuring by means of the laser radiation emitted from the rear side. With preference, the method is therefore developed such that, after the moving of the laser beam along the scribing line and/or after the moving of the substrate in relation to the laser beam along the scribing line, a front-electrode structure is applied to the structured absorber thin film and the laser beam is subsequently emitted onto the second side of the substrate along a further scribing line offset laterally from the first scribing line, is incident on the metallic back-electrode than film through the substrate and is set with laser pulses in the nano-, pica- or femtosecond range in such a way, and a relative movement between the laser beam and the substrate is carried out in such a way, that the absorber thin film arranged over the metallic back-electrode thin film is ablated together with the front-electrode structure along the further scribing line and a laser-influenced metallic back-electrode thin film remains on the substrate.

An advantageous variant of the method for the laser structuring is used if the front-electrode structure is formed as a front-electrode thin film or as a front-electrode thin film with a lattice-like metallic electron collecting structure arranged thereover.

With preference, for all the variants described thus far, the method for the laser structuring is used with a substrate of glass.

The method for the laser structuring is used with preference in the case of absorber thin films of a ternary or quaternary semiconductor, for example CIGS or CIS.

It applies to all of the variants of the method for the laser structuring that have been described thus far that the laser wavelength is chosen in the near infrared or visible spectral range. Possible laser wavelengths are for example 515 nm, 532 nm, 1030 nm, 1047 nm, 1053 nm, 1060 nm, 1064 nm, 1080 nm and 1150 nm. In particular, rare-earth doped solid-state lasers are suitable for this. Possible laser wavelengths are therefore the fundamental wavelengths thereof and higher harmonics.

Particularly clean cut lines are achieved with preference by the laser beam and/or the substrate being moved in such a way that a spatial overlap of the laser pulses of 10 to 50% along the scribing lines is ensured.

As a further preferred range for the pulse energy of the laser pulses that is used, it is provided with advantage that the pulse energy per pulse is chosen in the range of 1 to 100 μJ, with preference in the range of 15 to 30 μJ.

The invention also relates to a method for producing a thin-film solar module comprising monolithically interconnected thin-film solar cells in the substrate structure with the following steps:
providing a glass substrate,
depositing a metallic back-electrode thin film on the glass substrate,
carrying out a P1 laser structuring step of the metallic back-electrode thin film,
depositing an absorber thin film on the structured metallic back-electrode thin film,
carrying out a P2 laser structuring step of the absorber thin film,
depositing a front-electrode thin film on the structured absorber thin film,
carrying out a P3 laser structuring step of the absorber thin film together with the front-electrode thin film,
encapsulating the monolithically interconnected thin-film solar cells in a permanently weatherproof manner with a front-side encapsulating element and
attaching a permanently weatherproof electrical solar-module connection device on the substrate.

According to the invention, it is provided that the P2 laser structuring step and/or the P3 laser structuring step are carried out according to one of the previously described method variants for laser structuring.

In a preferred development of the production method, it is provided that the following, further method steps are carried out before the method step of encapsulating and attaching a connection device:
emitting a laser beam onto the substrate,
moving the laser beam along at least one scribing line over the substrate and/or moving the substrate in relation to the laser beam for producing at least one insulating trench by means of a relative movement between the laser beam and the substrate, the laser beam being emitted onto the second side the substrate, incident on the metallic back-electrode thin film through. the substrate and set with laser pulses in the pico- or femtosecond range in such a way, and the relative movement between the laser beam and the substrate being performed in such a way, that together with the metallic back-electrode thin film the absorber thin film arranged thereover and the front-electrode structure arranged on it are ablated. from the substrate along the scribing line.

The enumerated laser parameters of one and the same laser can be set in such a way that, unlike in the case of the P2 to P3 laser structuring steps, the molybdenum thin film is ablated with all of the films lying thereover. These insulating trenches create solar sub-modules on the same substrate. In this way, the entire monolithic structuring of a thin-film solar module is possible with a single laser device. As a result, production is much less costly in comparison with the prior art.

An exemplary embodiment is explained in more detail on the basis of the figures described below, in which:

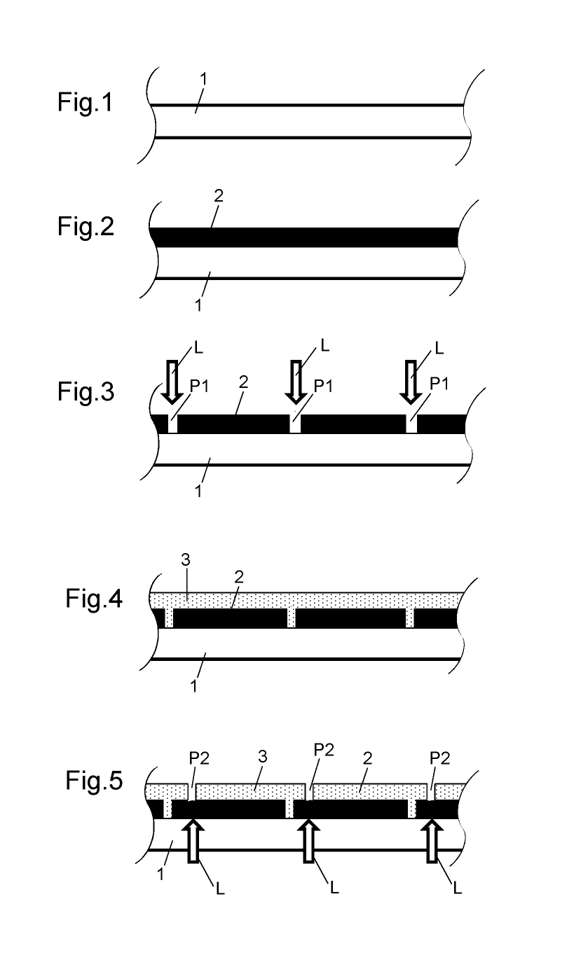

FIGS. 1 to 9 show the sequential and purely schematically represented sequence of the film deposition, structuring and encapsulation for producing a thin-film solar module, in which the method according to the invention for the laser structuring of thin films is used repeatedly.

According to FIG. 1, a glass substrate 1 is provided and, as shown in FIG. 2, a back-electrode thin film is sputtered on, for example in the form of a 100 to 200 nanometer thick molybdenum film. According to FIG. 3, a periodic structuring of the back-electrode thin film is performed by means of laser beams L. Either the laser beams L are moved along the substrate 1 by means of an optical system and/or the substrate 1 is moved under the fixed laser beam L. As a result by the relative movement between laser beam L and the substrate 1 along laser beam L defined trenches P1 are created in in the molybdenum thin film of the back-electrode thin film 2. Subsequently, as schematically shown in FIG. 4, an absorber thin film 3 is deposited onto these structured strips of the back-electrode thin film 2, extending over the full surface area of the structured strips and the trenches P1 lying in between. This absorber thin film 3 may consist of a number of sub-films, for example of a CIGS (Cu(In,Ga) (Se, S) 2) film, which is combined. with a CdS buffer film and usually has a thickness of less than two micrometers.

There then follows, according to FIG. 5, a process referred to as the P2 structuring step. This involves the absorber thin film 3 being removed down to the back-electrode thin film 2 along the trenches P2 adjacent the covered trenches P1. This process step is once again performed by using a laser beam L. Unlike in the case of the P1 structuring step, however, the laser is now directed from the rear, first through the glass substrate 1, onto the back-electrode thin film. The laser parameters can be suitably set in such a way as to induce from the back-electrode thin film 2 a shockwave that completely ablates the absorber thin film 3 lying over the back-electrode thin film 2 but leaves the back-electrode thin film 2 itself substantially intact. It can be seen microscopically that the back-electrode thin film 2 has been influenced by the laser beam L. For instance, the film thickness is usually reduced somewhat, but the loss of material is so small that the remaining metal thin film of the back-electrode thin film 2 is entirely sufficient for the function of the monolithically interconnected solar module. In addition, the properties are better in comparison with the surfaces of the back-electrode thin film 2 that are left behind by mechanical scraping methods.

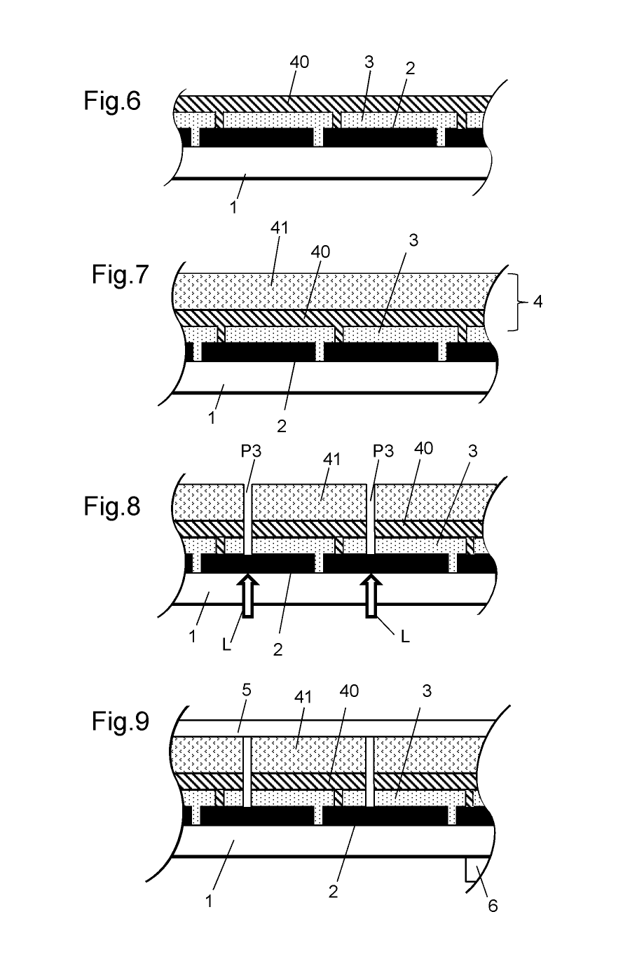

After that, according to FIG. 6, a transparent front-side electrode thin film 40 is deposited over the full surface area of the absorber thin film 3 structured with the trenches P2.

To complete the front-side electrode structure 4, an electrode collecting structure 41 is applied over the transparent front-side electrode thin film 40 in a step shown in FIG. 7. The electrode collecting structure 41 consists of a non-transparent network structure with good electrical conductivity that covers much less than 1% of the area of light incidence of the solar module.

These network structures are usually realized as films with thicknesses of many micrometers.

This is followed, according to FIG. 8, by the so-called P3 structuring. Once again adjacent and parallel to the covered trenches P2, the film assembly comprising the absorber thin film 3 and the front-side electrode structure 4 is removed along trenches P3 down to the back-electrode thin film 2. In a way similar to the P2 structuring shown in FIG. 5, this P3 structuring is performed by laser beams L, which are directed from the rear through the glass substrate 1 onto the back-electrode thin film 2. The setting of the laser parameters and the relative movement between the substrate 1 and the laser beam L is once again chosen in such a way that all of the thin films lying above the back-electrode thin film 2 formed from molybdenum and even films with a thickness of many micrometers are ablated. A back-electrode thin film 2 that is sufficiently thick and suitable in terms of its microstructure remains behind.

In the final step, according to FIG. 9, on the one hand a front-side encapsulating element 5 is applied to the light entry side. This front-side encapsulating element 5 may for example be formed by a second glass plate with a film of EVA (ethylene vinyl acetate) or a sufficiently weather-stable polymer film lying thereunder. As a result, the monolithically interconnected thin-film cells are encapsulated in a permanently weatherproof manner. On the other hand, a solar-module connection device 6 for the electrical contacting of the thin-film cells interconnected in series is also mounted on the module. The electrical contacts reaching from the solar-module connection device 6 through the substrate 1 to the thin-film cells are not represented in FIG. 9.

Suitable laser parameters for the described P2 or P3 structuring at laser wavelengths such as 1064 nm and 532 nm are pulse lengths in the picosecond range, with pulse energies in the range of 10 to 35 μJ, the relative movement being set in such a way that a spatial overlap between two successive pulses in the range of 10 to 50% is realized.

### LIST OF DESIGNATIONS

1 Substrate

2 Back-electrode thin film

3 Absorber thin film

4 Front-electrode structure

40 Front-electrode thin. film.

41 Electrode collecting structure

5 Front-side encapsulating element

6 Solar-module connection device

P1 Structuring trenches of the back-electrode thin film

P2 Structuring trenches of the absorber thin film

P3 Structuring trenches of the front-electrode structure

L Laser beam

1. A method for the laser structuring of thin films on a substrate for the production of monolithically interconnected thin-film solar cells with the following steps:
providing a laser of a laser wavelength,
providing a substrate (1) having a first side and a second side, which is transparent for the laser wavelength, the first side of the substrate having a metallic back-electrode thin film (2), and an absorber thin film (3) for thin-film solar cells being arranged on the metallic back-electrode thin film (2),
emitting a laser beam (L) onto the substrate
moving the laser beam (L) along a scribing line over the substrate (1) and/or moving the substrate (1) in relation to the laser beam (L) along a scribing line,
characterized in that
the laser beam (L) is emitted onto the second side of the substrate (1), is incident on the metallic back-electrode thin film (2) through the substrate (1) and is set with laser pulses in the nano-, pico- or femtosecond range and moved in such a way that the absorber thin film (3) arranged over the metallic back-electrode thin film (2) is ablated along the scribing line and a laser-influenced metallic back-electrode thin film (2) remains on the substrate.

2. The method for laser structuring as claimed in claim 1, characterized in that a front-electrode structure (4) is arranged over the absorber thin film (3) and in the region of the scribing line the absorber thin film (3) is ablated together with the front-electrode structure (4) located thereover.

3. The method for laser structuring as claimed in claim 1, characterized in that, after the moving of the laser beam (L) along the scribing line and/or after the moving of the substrate (1) in relation to the laser beam along the scribing line, a front-electrode structure (4) is applied to the structured absorber thin film and the laser beam (L) is subsequently emitted onto the second side of the substrate (1) along a further scribing line offset laterally from the first scribing line, is incident on the metallic back-electrode thin film (2) through the substrate (1) and is set with laser pulses in the nano-, pico- or femtosecond range in such a way, and a relative movement between the laser beam (L) and the substrate (1) is carried out in such a way, that the absorber thin film (3) arranged over the metallic back-electrode thin film (2) is ablated together with the front-electrode structure (4) along the further scribing line and a laser-influenced metallic back-electrode thin film (2) remains on the substrate.

4. The method for laser structuring as claimed in claim 2, characterized in that the front-electrode structure (4) is formed as a front-electrode thin film (40) or as a front-electrode thin film (40) with a lattice-like metallic electrode collecting structure (41) arranged thereover.

5. The method for laser structuring as claimed in claim 1, characterized in that the substrate (1) is formed from glass.

6. The method for laser structuring as claimed in claim 1, characterized in that the absorber thin film (2) is formed as a ternary or quaternary semiconductor.

7. The method for laser structuring as claimed in claim 1, characterized in that the laser wavelength of the laser beam (L) is chosen in the near infrared or visible spectral range.

8. The method for laser structuring as claimed in claim 1, characterized in that the laser beam (L) and/or the substrate (1) is moved in such a way that a spatial overlap of the laser pulses of 10 to 50% along the scribing lines is ensured.

9. The method for laser structuring as claimed in claim 1, characterized in that the pulse energy per pulse is chosen in the range of 1 to 100 μJ, with preference in the range of 15 to 30 μJ.

10. A method for producing a thin-film solar module comprising monolithically interconnected thin-film solar cells in the substrate structure with the following steps:
providing a substrate (1) of glass,
depositing a metallic back-electrode thin film on the substrate (1),
carrying out a P1 laser structuring step of the metallic back-electrode thin film (2),
depositing an absorber thin film (3) on the structured metallic back-electrode thin film (2),
carrying out a P2 laser structuring step of the absorber thin film (3),
depositing a front-electrode thin film (40) on the structured absorber thin film (3),
carrying out a P3 laser structuring step of the absorber thin film (3) together with the front-electrode thin film (40),
encapsulating the monolithically interconnected thin-film solar cells in a permanently weatherproof manner with a front-side encapsulating element (5) and
attaching a permanently weatherproof electrical solar-module connection device (6) on the substrate (1),
characterized in that the P2 laser structuring step and/or the P3 laser structuring step are carried out according to one of the methods for laser structuring as claimed in claim lone of claims 1 to 9.

11. The production method as claimed in claim 10, characterized in that the following, further method steps are carried out before the method step of encapsulating and attaching a connection device:
emitting a laser beam (L) onto the substrate,
moving the laser beam (L) along at least one scribing line (S) over the substrate (1) and/or moving the substrate (1) in relation to the laser beam (L) for producing at least one insulating trench (I1, I2, I3, I4) by means of a relative movement between the laser beam (L) and the substrate (1), the laser beam (1) being emitted onto the second side of the substrate (1), incident on the metallic back-electrode thin film (2) through the substrate (1) and set with laser pulses in the pico- or femtosecond range in such a way, and the relative movement between the laser beam (L) and the substrate (1) being performed in such a way, that together with the metallic back-electrode thin film (2) the absorber thin film (3) arranged thereover and the front-electrode structure (4) arranged on it are ablated from the substrate (1) along the scribing line (S).
